(19) United States
(12) Patent Application Publication
(10) Pub. No.: US 2026/0190423 A1
(43) Pub. Date: Jul. 2, 2026

(54) HIGH ELECTRON MOBILITY TRANSISTOR WITH LEAKAGE BLOCKING STRUCTURE

(71) Applicant: TEXAS INSTRUMENTS INCORPORATED, Dallas, TX (US)

(72) Inventors: Zhikai Tang, Sunnyvale, CA (US); James Teherani, Plano, TX (US); Kevin Lee, Allen, TX (US); Pilsung Park, Dallas, TX (US); Chang Soo Suh, Allen, TX (US)

(21) Appl. No.: 19/002,268

(22) Filed: Dec. 26, 2024

(51) Int. Cl. H10D 64/23; H10D 30/47; H10D 62/85

(52) U.S. Cl. CPC H10D 64/258; H10D 30/475; H10D 62/8503

(57) ABSTRACT

A semiconductor device includes, in part, a semiconductor layer including an isolation region and an active region. The semiconductor device further includes, in part, first, second, and third contacts being at least partially on the active region. The semiconductor device further includes, in part, first and second gates extending from the active region into the isolation region. The first gate is laterally between the first and second contacts, and the second gate is laterally between the second and third contacts. The first and second gates include, respectively, first and second leakage blocking extensions that are proximate a boundary between the isolation region and the active region.

### BACKGROUND

A high electron mobility transistor (HEMT) may include a heterojunction near which a channel may be formed. The heterojunction may be formed using different semiconductor materials. The channel may be turned on or off by applying an appropriate voltage to a gate structure. Gallium nitride (GaN)-based HEMT devices generally have a high breakdown field, high electron mobility, low resistance, high current, faster-switching speed, high thermal conductivity, and excellent reverse-recovery performance, and thus may be suitable for applications where a low-loss and high-efficiency performance is desired, such as power electronics (e.g., power switches), radio frequency (RF) circuits, and the like.

### SUMMARY

This Summary is provided to introduce examples of disclosed concepts in a simplified form, which are further described below in the Detailed Description including the drawings provided.

According to certain aspects, a semiconductor device may include, in part, a semiconductor layer including an isolation region and an active region. The semiconductor device may further include, in part, first, second, and third contacts associated with the source and drain regions of the semiconductor device, and that are least partially on the active region. The semiconductor device may further include, in part, first and second gates extending from the active region into the isolation region. The first gate is laterally between the first and second contacts, and the second gate is laterally between the second and third contacts. The first and second gates include, respectively, first and second leakage blocking extensions that are proximate a boundary between the isolation region and the active region.

According to certain aspects, a semiconductor device may include, in part, a semiconductor layer including an isolation region and an active region. The semiconductor device may further include, in part, first, second, and third contacts associated with the source and drain regions of the semiconductor device, and that are least partially on the active region. The semiconductor device may further include, in part, first and second gates extending from the active region into the isolation region. The first gate is laterally between the first and second contacts, and the second gate is laterally between the second and third contacts. The first and second gates each have a first region and a second region, the second regions of the first and second gates proximate a boundary between the isolation region and the active region. The second regions has a higher threshold voltage for enabling a current forming a channel than the first regions.

According to certain aspects, a semiconductor device may include a semiconductor layer including an isolation region and an active region. The semiconductor device may further include, in part, first, second, and third contacts associated with the source and drain regions of the semiconductor device, and that are least partially on the active region. The semiconductor device may further include first and second gate structures, each including a second semiconductor layer (e.g., pGAN) extending from the active region into the isolation region. The second semiconductor layer of the first gate structure being laterally between the first and second contacts, and the second semiconductor layer of the second gate structure being laterally between the second and third contacts. The first and second gate structures each have a first region and a second region. The second regions of the first and second gate structures proximate a boundary between the isolation region and the active region. The second regions have a different structure from the first regions.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings. This Summary is provided to introduce examples of disclosed concepts in a simplified form, which are further described below in the Detailed Description including the drawings provided.

### BRIEF DESCRIPTION OF THE DRAWINGS

Illustrative examples are described in detail below with reference to the following figures.

FIG. 1 is a cross-sectional view of a high electron mobility transistor (HEMT), according to some examples.

FIG. 2A is a plan view of a semiconductor device, according to some examples.

FIG. 2B is a perspective view of the semiconductor device of FIG. 2A, according to some examples.

FIG. 3 is a plan view of a semiconductor device, according to some examples.

FIG. 4A is a plan view of a semiconductor device, according to some examples.

FIG. 4B is a plan view of a semiconductor device, according to some examples.

FIG. 4C is a plan view of a semiconductor device, according to some examples.

FIG. 4D is an expanded view of a portion of the semiconductor device of FIG. 4C, according to some examples.

FIG. 5 is a plan view of a semiconductor device, according to some examples.

FIG. 6 is a plan view of a semiconductor device, according to some examples.

FIG. 7 is a plan view of a semiconductor device, according to some examples.

FIG. 8 is a plan view of a semiconductor device, according to some examples.

FIG. 9 is a plan view of a semiconductor device, according to some examples.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

Aspects of the present disclosure relate to a semiconductor device. In one example, the semiconductor device is a field-effect transistor (FET) that includes, in part, an active region and an isolation region. The FET further includes, in part, first, second and third contacts associated with source and drain regions of the FET. The FET further includes, in part, first and second gates extending from the active region into the isolation region. The first gate is laterally between the first and second contacts, and the second gate is laterally between the second and third contacts.

In some examples, the first and second gates include, respectively, first and second leakage blocking extensions in proximity to a boundary between the isolation region and the active region. The leakage blocking extensions mitigate leakage current between the source and drain regions of the FET. In some examples, the first and second leakage blocking extensions are connected to one another to bridge the first and second gates. In one example, the FET is a GaN-based power FET.

A GaN-based field-effect transistor, such as a GaN-based HEMT, may include a heterojunction formed by a channel layer (e.g., a GaN layer) and a barrier layer (e.g., an aluminum gallium nitride (AlGaN) layer). A high-density two-dimensional electron gas (2 DEG) region may be formed at the heterojunction to operate as the transistor channel. For example, the 2 DEG layer may have a sheet charge density greater than about 1.0×10¹³ cm⁻², and thus can have a low static on-state resistance. GaN-based HEMTs are suitable for use in high frequency and high power applications due to, for example, their high breakdown field, high electron mobility, low static resistance, and high thermal conductivity.

Some GaN-based HEMTs may have gate structures entirely within the active region where 2 DEG can be formed, which can cause current crowding issues around the gate structures. One way to mitigate the current crowding issues is by creating, around the active region, an isolation region where 2 DEG is not to be formed, and extending the gate structures from the active region into the isolation region. But such arrangements can create leakage paths, between the source and drain, at the boundary between the active and isolation regions. As to be described here, the gate structures can include various leakage blocking structures proximate the boundary between the active and isolation regions to mitigate (or eliminate) the leakage paths.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2 DEG at the heterojunction interface.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

GaN-based HEMTs include heterostructures that may induce two-dimensional electron gas (2 DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2 DEG may be generated in the GaN layer near the interface of the heterostructure to form a conductive channel in the GaN layer (which is thus referred to as the channel layer). Compared to silicon-based transistors, GaN-based transistors generally have high breakdown electric field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement mode high electron mobility transistor (e-HEMT) or a depletion mode high electron mobility transistor (d-HEMT). For example, the gate structure of an e-HEMT may include a p-type GaN (p-GaN) layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2 DEG channel under the p-GaN gate structure, such that the conductive path between the source and drain may be disabled and thus the e-HEMT may be turned off when no gate drive voltage is applied to the gate electrical contact. When a positive voltage above the gate threshold voltage is applied to the gate electrical contact, the gate structure may attract electrons such that the 2 DEG under the gate structure may be replete with electrons, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2 DEG under the gate structure may not be depleted such that the conductive path in the channel layer between the drain structure and the source structure may be enabled even without a positive gate voltage. A d-HEMT can be turned off by applying a negative gate voltage to the gate electrical contact to deplete electrons from the 2 DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

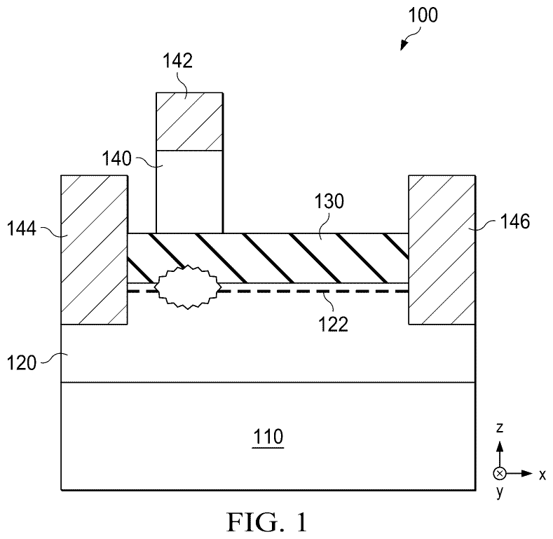

FIG. 1 is a cross-sectional view of an example of a high electron mobility transistor (HEMT) 100. In the illustrated example, HEMT 100 is an e-mode GaN-based transistor that includes a substrate 110, a channel layer 120, a barrier layer 130, a gate structure, a source structure, and a drain structure. Substrate 110 may include, for example, a silicon substrate, a silicon carbide substrate, a semiconductor-on-insulator (SOI) substrate, a sapphire substrate, a gallium nitride (GaN) substrate, a gallium arsenide (GaAs) substrate, an engineered GaN substrate (a Qromis™ Substrate Technology (QST) substrate), a substrate including another semiconductor material that has a bandgap wider than the bandgap of silicon, or any other suitable substrate. In one example, substrate 110 may include a bulk silicon substrate, and may also include one or more transition layers or buffer layers of suitable materials for accommodating the lattice mismatch between substrate 110 and channel layer 120 (e.g., to reduce or minimize lattice defect generation and/or propagation in channel layer 120). For example, the transition layers or buffer layers may have a gradient concentration of one or more elements in a surface normal direction (e.g., z direction) of substrate 110 to gradually change the lattice constant.

Channel layer 120 and barrier layer 130 may be epitaxially grown on substrate 110 to form a heterostructure that may induce a 2 DEG 122 layer near the interface between channel layer 120 and barrier layer 130 due to the different energy band structures of channel layer 120 and barrier layer 130. 2 DEG 112 may conduct current in a two-dimensional plane (e.g., an x-y plane). In some examples, channel layer 120 may be a portion of substrate 110. Channel layer 120 may include, for example, a GaN layer, an AlGaN layer, or an InAlN layer. In some examples, the material of channel layer 120 may include an unintentionally doped material, such as a material doped by diffusion of dopants from another layer, or includes an intrinsic material. Barrier layer 130 may include, for example, an AlGaN layer. Other materials may also be used for channel layer 120 and barrier layer 130. For example, channel layer 120 may include indium aluminum gallium nitride (InᵢAlⱼGa₁₋ᵢ₋ⱼN) (where 0≤i≤1, 0≤j≤1, and 0≤i+j≤1), and barrier layer 130 may include indium aluminum gallium nitride (InₖAlₗGa₁₋ₖ₋ₗN) (where 0≤k≤1, 0≤l≤1, and 0≤k+l≤1).

The gate structure of HEMT 100 may include a gate semiconductor layer 140 over an upper surface of barrier layer 130. In some examples, gate semiconductor layer 140 may include a p-doped semiconductor layer. For example, gate semiconductor layer 140 may include a GaN layer, or more generally, an InₘAlₙGa₁₋ₘ₋ₙN layer (where 0≤m<1, 0≤n<1, and 0≤m+n≤1). The p-type dopants for doping gate semiconductor layer 140 may include magnesium (Mg), carbon (C), zinc (Zn), and the like, or a combination thereof. In examples where gate semiconductor layer 140 includes GaN doped with a p-type dopant, gate semiconductor layer 140 may be referred to as a p-GaN layer. In some examples, a concentration of the dopant that is electrically activated in gate semiconductor layer 140 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 140 may be formed by epitaxial growth and selective etching using an etch mask, or may be formed by selective area growth using a growth mask. The etch mask or growth mask may define the shape and size of gate semiconductor layer 140. The doping density and the thickness of p-doped gate semiconductor layer 140 and the thickness of barrier layer 130 under gate semiconductor layer 140 may be selected such that the p-doped gate semiconductor layer 140 may deplete 2 DEG 122 under gate semiconductor layer 140, such that HEMT 100 is turned off without a positive gate voltage and may be turned on by applying a positive voltage to the gate structure.

A gate electrical contact 142 may be formed on gate semiconductor layer 140 to apply a gate voltage to gate semiconductor layer 140. Gate electrical contact 142 may be electrically coupled to a gate drive circuit though electrical interconnects such as conductive traces and/or vias (now shown). In some examples, gate electrical contact 142 may laterally extend beyond gate semiconductor layer 140 to form a gate field plate, for example, to reduce current collapse and dynamic on-state resistance, and increase the breakdown voltage. Gate electrical contact 142 may include one or more metal and/or metal alloy materials having high electrical conductivity.

At the source region of HEMT 100, a source electrical contact 144 may extend through barrier layer 130 and contact a source region of channel layer 120. Source electrical contact 144 may include a metal or metal alloy and may form a low-barrier metal-to-semiconductor contact (e.g., an ohmic contact) with channel layer 120. In some examples, source electrical contact 144 may not extend through barrier layer 130 and may be electrically coupled to the source region of channel layer 120 through, for example, tunneling effects. In some examples, one or more source field plates may be formed and may be coupled to source electrical contact 144. The source field plates may be used to reduce current collapse and dynamic on-state resistance and/or increase the breakdown voltage of HEMT 100.

At the drain region of HEMT 100, a drain electrical contact 146 may extend through barrier layer 130 and contact a drain region of channel layer 120. Drain electrical contact 146 may include a metal or metal alloy and may form a low-barrier metal-to-semiconductor contact (e.g., an ohmic contact) with channel layer 120. In some examples, drain electrical contact 146 may not extend through barrier layer 130 and may be electrically coupled to the source region of channel layer 120 through, for example, tunneling effects.

Each of gate electrical contact 142, source electrical contact 144, and drain electrical contact 146 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or a combination thereof. In some examples, the alloy may include, for example, titanium tungsten aluminum (TiWAl) or titanium aluminum nitride (TiAlN), or a combination thereof.

In some examples, HEMT 100 may include one or more dielectric layers (not shown in FIG. 1A) that isolate and protect the gate structure, drain structure, and source structure. The one or more dielectric layers may include a same dielectric material or different dielectric materials deposited in one or more deposition processes. For example, the one or more dielectric layers may include an oxide-based material or a nitride-based material, such as silicon oxide (e.g., a phosphosilicate glass (PSG)), aluminum oxide, silicon nitride, and the like. In some examples, the one or more dielectric layers may further include one or more etch stop layers, such as silicon nitride (SiN) and the like, for controlling the etch depth of etching processes (e.g., for patterning a dielectric or metal layer).

In some examples, the electrical contacts or other metal electrical interconnects in HEMT 100 may each include one or more metal barrier layers and/or one or more adhesion layers (e.g., titanium nitride (TiN), tantalum nitride (TaN), and the like, or a combination thereof) between the metal material (e.g., Al, Cu, W, and the like, or a combination thereof) and the one or more dielectric layers. The one or more metal barrier layers may prevent the diffusion of metal atoms into the one or more dielectric layers. The one or more adhesion layers may be used to improve the adhesion of the metal material to the dielectric material of the one or more dielectric layers to reduce or avoid defects and reliability issues such as interfacial delamination.

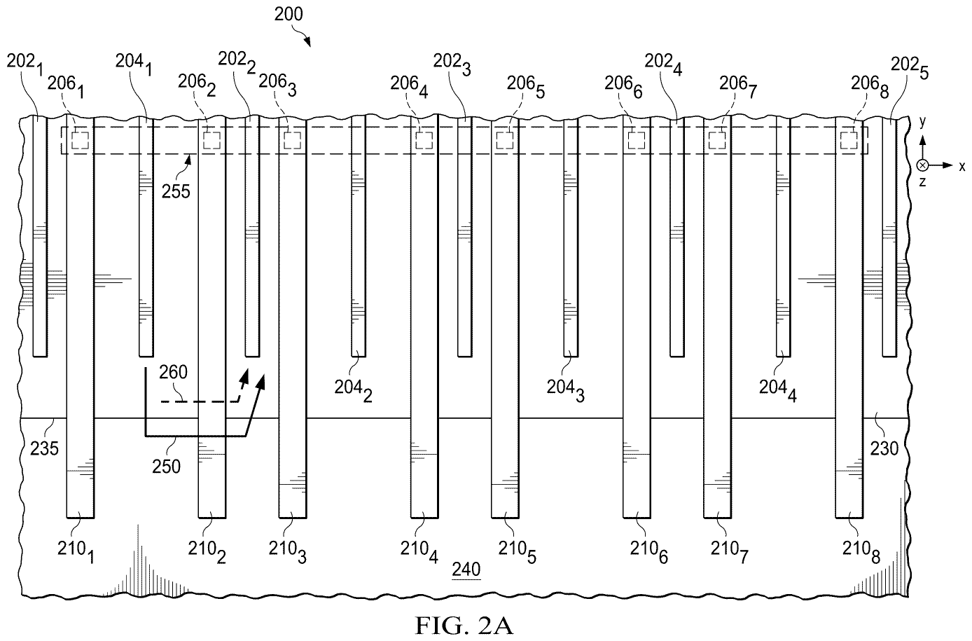

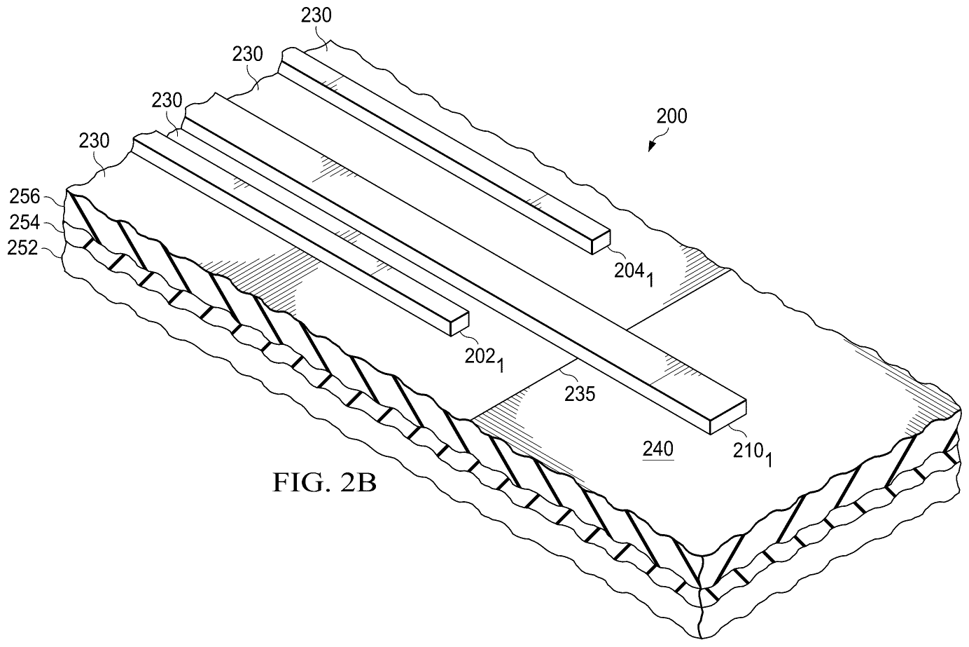

FIG. 2A is a plan view of a semiconductor device 200 according to some examples. Semiconductor device 200, which in this example is a FET, is shown as including, in part, a multitude of parallel gate structures (alternatively referred to herein as gate fingers, or gates), 8 of which, namely 210₁, 210₂ . . . 210₈ are shown in FIG. 2A. Positioned along opposing sides of each gate fingers 210ᵢ (i is an index ranging from 1 to 8 in this example) are a source contact—coupled to a source region of the FET—and a drain contact coupled to a drain region of the FET. For example, source contact 202₁ is shown as being positioned to the left of gate finger 210₁, and drain contact 204₁ is shown as being positioned to the right of gate finger 210₁. In a similar manner, source contact 202₃ is shown as being positioned to the left of gate finger 210₅, and drain contact 204₃ is shown as being positioned to the right of gate finger 210₅. Gate fingers 210ᵢ are connected to one another via metal interconnect 250 and gate contacts 206ᵢ. Although not shown in FIG. 2A, it is understood that the source contacts are connected to one another via a metal interconnect, and drain contacts are connected to one another via another metal interconnect.

Boundary line 235 is defined by a patterned mask separating active region 230 of FET 200 from isolation region 240 of FET 200. Isolation region 240 includes implanted impurities in order to inhibit the formation of a 2 DEG region due to, for example, the damage imparted to the semiconductor crystal (e.g., GaN crystal) during the implantation. Under ideal conditions, current flow in the isolation region is therefore inhibited. In some examples, the ion dosage to be implanted can be in the range of 10¹²-10¹⁸ cm⁻², and there can be 50%-100% of the ion dosage remaining in the isolation region. Also, the isolation boundary can have a width due to, for example, the scattering and straggling of the ions the semiconductor crystal. In some examples, the isolation boundary can have a width of 50-1000 nanometers (nm).

If the gate fingers terminate within the active region 230 and do not extend into the isolation region 240 (not shown in FIG. 2A) so as to avoid the dual subthreshold voltages associated with FET 200, during the normal mode of operation when the transistor is switching, current crowding may occur near the edges of source/drain contacts facing the boundary of the isolation region, which in turn, may adversely affect operational safety of the transistor.

To mitigate the current crowding effect and avoid damage to the transistor, gate fingers may extend into the isolation region. In some examples, the gate fingers may extend into the isolation region by, for example, 0.1-10 micrometers (um). However, by extending the gate fingers into the isolation region, FET 200 may have two subthreshold voltages, one of which is caused by gate fingers 210ᵢ extending into the isolation region, where a current path 250 can be enabled between the source and drain contacts through isolation region 240. The other subthreshold voltage is intrinsic to the transistor and is defined by, for example, the characteristics of the active region, gate length, and the like, where a current path 260 can be enabled between the source and drain contacts through active region 230. Accordingly, when FET 200 is in the subthreshold region and a voltage difference is induced between the source and drain contacts of the transistor, a leakage current may flow between the source and drain contacts along path 250 passing through active region 230, boundary 235, and isolation region 240, as well as along path 260 in active region 230. Therefore, by extending the gate fingers into the isolation region, a tradeoff is made between mitigating the current crowding effect and the dual subthreshold voltage characteristics of the transistor.

FIG. 2B is a perspective view of FET 200 of FIG. 2A, according to one example. FET 200 is shown as having a vertical stack (e.g., stacked along the z-axis of FIG. 2A) of layers including, in part, a substrate 252, a buffer layer 254 above substrate 252, and a barrier layer 256 above buffer layer 254. For simplicity, only one of the gate fingers, namely gate finger 210_{1,} only one source contact 202₁, and only one drain contact 204₁ of FET 200 are shown in FIG. 2B. As was also described with reference to FIG. 2A, boundary line 235 is defined by a patterned mask that separates isolation region 240 from active region 230.

Referring to FIGS. 2A and 2B, in various examples, substrate 252 may include, a silicon substrate, a silicon carbide substrate, an SOI substrate, a sapphire substrate, a GaN substrate, a GaAs substrate, an engineered GaN substrate (a QST substrate), a substrate including another semiconductor material that has a bandgap wider than the bandgap of silicon, or any other suitable substrate. In some examples, buffer layer 254 may include GaN; and barrier layer 256 may include AlGaN. In some examples, the gate fingers include p-type GaN (p-GaN). In some examples, the thickness of AlGaN barrier layer in the isolation region 240 is greater than the thickness of AlGaN barrier in the active layer 230. In some examples, the thickness of the GaN buffer layer over the active region is greater than the thickness of the GaN buffer layer over the isolation region. The drain/source contacts and the gate metal positioned over the p-GaN gate fingers may include titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or any combinations thereof. In some examples, the alloy may include, for example, titanium tungsten aluminum (TiWAl), titanium aluminum nitride (TiAlN), or a combination thereof.

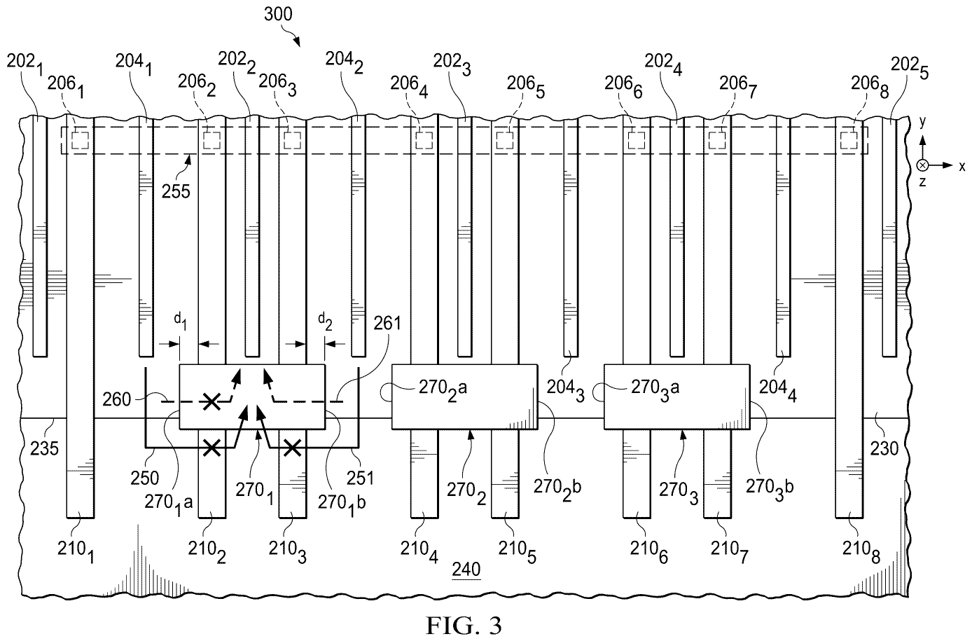

FIG. 3 is a plan view of a semiconductor device 300 according to some examples. Semiconductor device 300, which in this example is a FET, is shown as including, in part, a multitude of parallel gate fingers 210ᵢ, where i is an index ranging from 1 to 8 in this example. Positioned along opposing sides of each gate finger are a source ohmic contact and a drain ohmic contact. For example, source contact 202₁ is shown as being positioned to the left of gate finger 210₁, and drain contact 204₁ is shown as being positioned to the right of gate finger 210₁. Gate fingers 210ᵢ are connected to one another via metal interconnect 255 and gate contacts 206ᵢ. Although not shown in FIG. 3, it is understood that the source contacts are connected to one another via a metal interconnect, and drain contacts are connected to one another via another metal interconnect.

Boundary line 235 is defined by a patterned mask separating active region 230 of FET 300 from isolation region 240 of FET 300. Isolation region 240 is formed by implanting ions to inhibit the formation of a 2 DEG region due to, for example, the damage imparted to the semiconductor crystal during the implantation. The ion implantation causes FET 300 to have two subthreshold voltages, a first one of which is caused by gate fingers 210ᵢ extending into the isolation region 240. The second subthreshold voltage, which is higher than the first subthreshold voltage, is intrinsic to the transistor and is defined by, for example, the characteristics of the active region, gate length, and the like.

To mitigate the leakage current resulting from the lower subthreshold voltage near the boundary between the active region 230 and isolation region 240, adjacent gate fingers positioned on opposing sides of each source contact can have leakage blocking extensions that proximate boundary 235. For example, leakage blocking extension 270₁, connected between gate fingers 210₂ and 210₃, blocks the current between drain contacts 204₁/204₂ and source contact 202₂ that would otherwise flow along directions 250/251 in isolation region 240, and along directions 260/261 in active region 230. Leakage blocking extension 270ᵢ may be formed from the same material as gate fingers 210ᵢ. For example, gate fingers 210ᵢ and 270ᵢ may be formed using p-GaN.

In a similar manner, leakage blocking extension 270₂, connected between gate fingers 210₄ and 210₅, blocks the current flow between drain contacts 204₂/204₃ and source contact 202₃; and leakage blocking extension 270₃, connected between gate fingers 210₆ and 210₇, blocks the current flow between drain contacts 204₃/204₄ and source contact 202₄. Edges 270₁a and 270₁b of leakage blocking extension 270₁, that are shown as being parallel to the lateral gate fingers 210ᵢ along the y-axis, extend beyond the parallel edges of gate fingers 210₂ and 210₃ by distances d₁ and d_{2,} respectively. Distances d₁ and d₂ may or may not be equal. In a similar manner, edges 270₂a and 270₂b of leakage blocking extension 270₂ extend beyond the edges of gate fingers 210₄ and 210₅ along the y-axis; and edges 270₃a and 270₃b of leakage blocking extension 270₃ extend beyond the edges of gate fingers 210₆ and 210₇ along the y-axis, as shown.

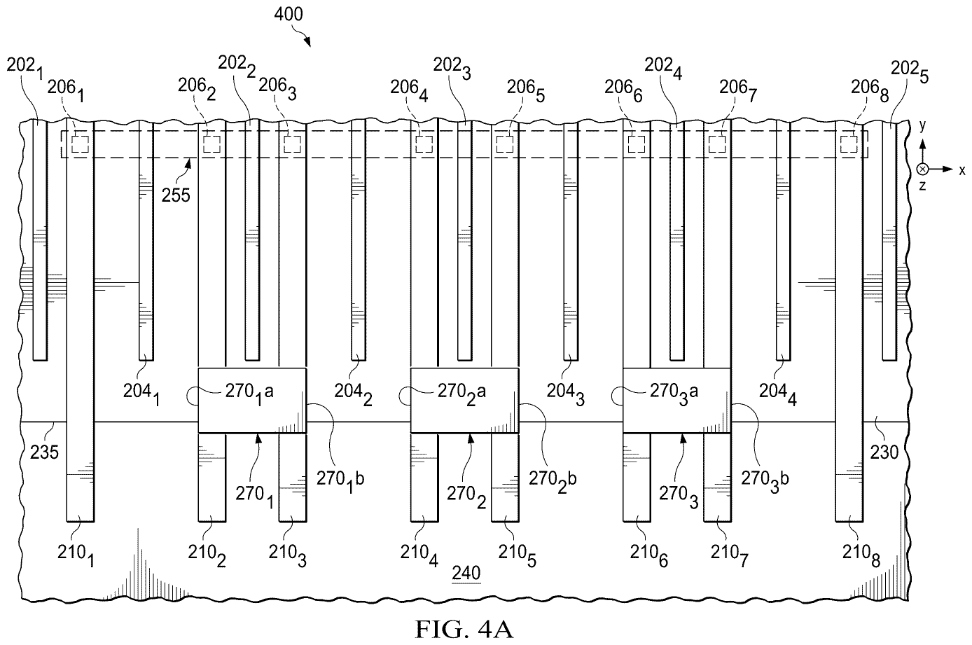

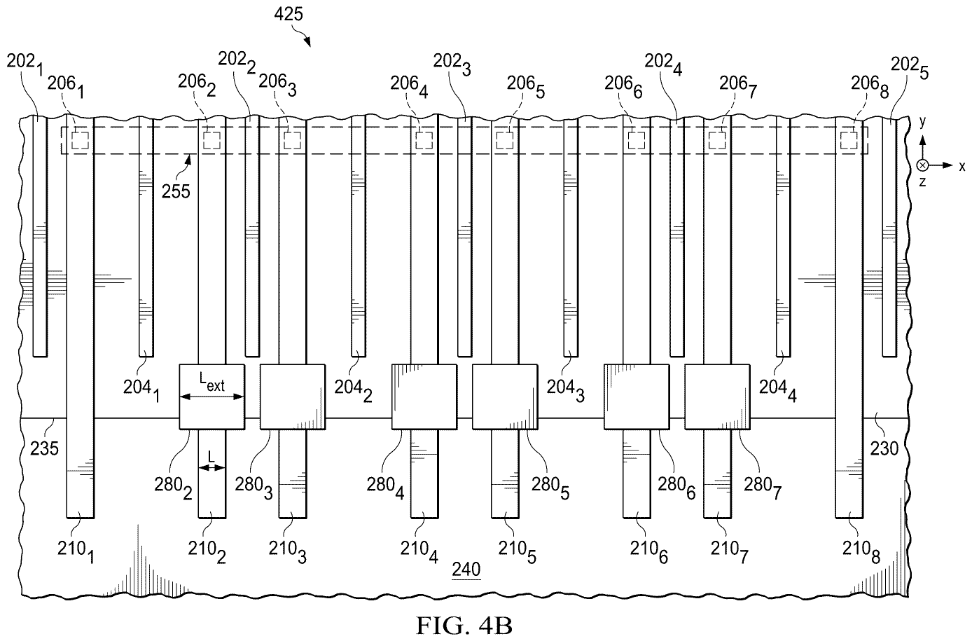

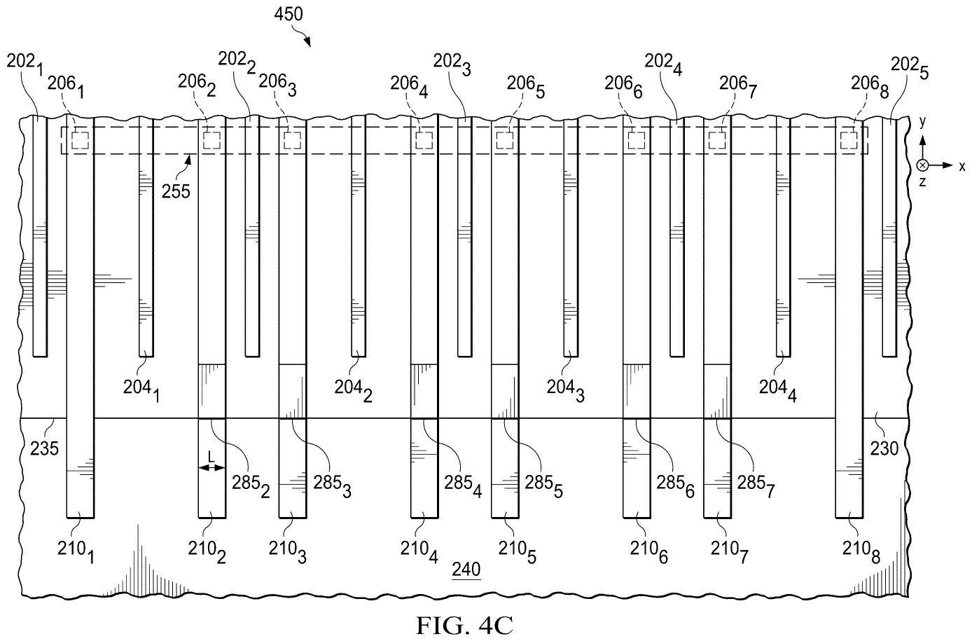

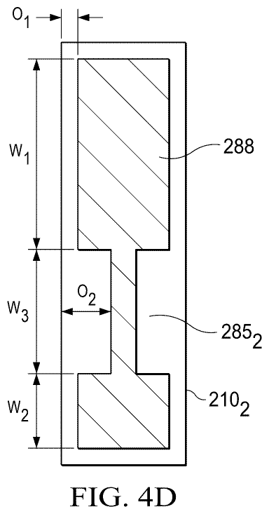

FIG. 4A is a plan view of a semiconductor device 400 according to some examples. Semiconductor device 400, which in this example is a FET, is similar to FET 300 except that in FET 400 the parallel edges of the leaking blocking extension coincide with and do not extend beyond the edges of their associated gate fingers along the x-direction. For example, edge 270₁a of leakage blocking extension 270₁ is coincident with and does not extend beyond the left edge of gate finger 210₂, and edge 270₁b of leakage blocking extension 270₁ is coincident with and does not extend beyond the right edge of gate finger 210₄.

As described above, leakage blocking extensions 270 are proximate boundary 235. In some examples, as shown in FIGS. 3 and 4A, overlap boundary 235. In some examples (not shown in the figures), leakage blocking extensions 270 may be entirely within active region 240 and can be spaced from boundary 235 by a distance of, for example, 0.1 to 5 um.

FIG. 4B is a plan view of a semiconductor device 425 according to some examples. Semiconductor device 425, which in this example is a FET, is shown as including, in part, a multitude of parallel gate fingers 210ᵢ, where i is an index ranging from 1 to 8 in this example. Positioned along opposing sides of each gate finger are a source ohmic contact, and a drain ohmic contact. For example, source contact 202₁ is shown as being positioned to the left of gate finger 210₁, and drain contact 204₁ is shown as being positioned to the right of gate finger 210₁. Gate fingers 210ᵢ are connected to one another via metal interconnect 250 and gate contacts 206ᵢ. Although not shown in FIG. 4B, it is understood that the source contacts are connected to one another via a metal interconnect, and drain contacts are connected to one another via another metal interconnect.

Boundary line 235 is defined by a patterned mask separating active region 230 of FET 425 from isolation region 240 of FET 425. Isolation region 240 is formed by implanting ions to inhibits the formation of a 2 DEG region due to, for example, the damage imparted to the semiconductor crystals during the implantation. The ion implantation causes FET 425 to have two subthreshold voltages. The first subthreshold voltage is caused by extending gate fingers 210ᵢ into isolation region 240. The second subthreshold voltage is intrinsic to the transistor and is defined by, for example, the characteristics of the active region, gate length, and the like. The second subthreshold voltage is higher than the first subthreshold voltage.

Each gate finger 210ᵢ is adapted to have an associated high threshold voltage structure to mitigate the current leakage resulting from the lower subthreshold voltage near the boundary between the active region 230 and isolation region 240. In the example shown in FIG. 4B, the high threshold voltage structure includes an expanded gate area that is wider along the x direction near the boundary of the active region 230 and isolation region 240. The expanded width of the gate fingers along the x direction increases the channel length, thereby increasing the threshold voltage and, as a consequence, lowering the leakage current. For example, gate finger 210₂ is shown as including a high threshold voltage structure 280₂ that provides a channel length of Lₑₓₜ which is longer than the channel length L provided by the remaining portions of gate finger 210₂. The longer channel length Lₑₓₜ provided by high threshold voltage structure 280₂ increases the threshold voltage, and therefore reduces the leakage current between source contact 204₂ and drain contact 202₂. A portion of high threshold voltage structure 280₂ is shown as partially overlapping the isolation region 240. Each of the remaining gate fingers 210₁ and 210₃-210₈ are also shown as having an associated high threshold voltage structure, namely high threshold voltage structures 280₁ and 280₃-280₈, respectively.

High threshold voltage structures 280 are examples of leakage blocking extensions 270 and are proximate boundary 235. In some examples, as shown in FIG. 4B, overlap boundary 235. In some examples (not shown in the figures), high threshold voltage structures 280 may be entirely within active region 240 and can be spaced from boundary 235 by a distance of, for example, 0.1 to 5 um.

In accordance with some examples, the high threshold voltage structure associated with each gate finger provides a relatively larger offset between the gate finger and the metal layer formed above that gate finger. FIG. 4C is a plan view of a semiconductor device 450, according to some examples. Semiconductor device 450, which in this example is a FET, is shown as including, in part, a multitude of parallel gate 210ᵢ, where i is an index ranging from 1 to 8 in this example. In the example of FIG. 4C, each gate finger 210ᵢ is shown as having a high threshold voltage structure 285ᵢ in which the gate offset is larger than the gate offset in the remaining portion of the gate finger, as described further below with reference to FIG. 4D.

FIG. 4D is an expanded plan view of gate finger 210₂ of FET 450 of FIG. 4C. Gate finger 210₂, which may include a p-type GaN (p-GaN), is shown as having an ohmic metal layer (contact) 288 formed thereon that has a gate offset of O₁ outside the high threshold voltage structure 285₂ and along a first portion of the gate width W₁ and a second portion of the gate width W₂. The width of the metal contact 288 within high threshold voltage structure 285₂ (also identified in FIG. 4D as having a gate width W₃) is O₂ which is smaller than O₁, thus giving rise to a higher threshold voltage associated with high threshold voltage structure 285₂. Although not shown in FIG. 4C, in some examples, the high threshold voltage structures 285ᵢ extend into the isolation region 240. In some examples, a higher threshold voltage is achieved by selective epitaxial growth and/or localized p-GaN activation below the high threshold voltage structures 285ᵢ.

High threshold voltage structures 285 are examples of leakage blocking extensions 270 and are proximate boundary 235. In some examples, as shown in FIG. 4C, may overlap with boundary 235. In some examples (not shown in the figures), high threshold voltage structures 285 may be entirely within active region 240 and can be spaced from boundary 235 by a distance of, for example, 0.1 to 5 um.

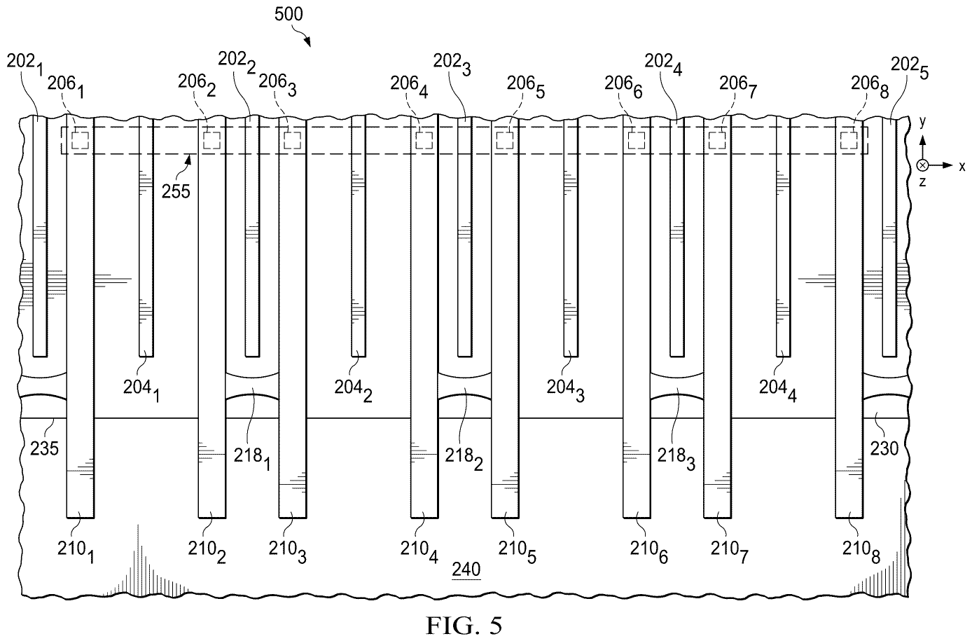

FIG. 5 is a plan view of a semiconductor device 500 according to some examples. Semiconductor device 500, which in this example is a FET, includes, in part, a multitude of parallel gate fingers 210ᵢ, 8 of which, namely 210₁, 210₂ . . . 210₈ are shown in FIG. 5. Positioned along opposing sides of each gate finger 210ᵢ (i is an index ranging from 1 to 8 in this example) are a source contact, and a drain contact. For example, source contact 202₁ is shown as being positioned to the left of gate finger 210₁, and drain contact 204₁ is shown as being positioned to the right of gate finger 210₁. Although not shown, it is understood that gate fingers 210ᵢ are connected to one another via a first metal interconnect; source contacts are connected to one another via a second metal interconnect; and drain contacts are connected to one another via a third metal interconnect. Boundary line 235 is defined by a patterned mask separating active region 230 of FET 500 from isolation region 240. Isolation region 240 is formed by ion implantation to inhibit the formation of a 2 DEG region due to, for example, the damage imparted to the semiconductor crystal, such as AlGaN and GaN crystals.

To mitigate the current leakage that may results from the lower subthreshold voltage near the boundary between the active region 230 and isolation region 240 as described in detail above, adjacent gate fingers that are positioned on opposing sides of each source contact are connected to one another via a leakage cut-off structure in the active region 230. The leakage cut-off structure includes the same material(s) as that which is included in the gate fingers, e.g., p-GaN. For example, leakage cut-off structure 218₁, shown as connecting gate fingers 210₂ and 210₃ in active region 230, minimizes the leakage current between drain contact 204₁ and source contact 202₂. In a similar manner, leakage cut-off structure 218₂, shown as connecting gate fingers 210₄ and 210₅, minimizes the leakage current flow between drain contact 204₂ and source contact 202₃; and leakage cut-off structure 218₃, shown as connecting gate fingers 210₆ and 210₇, minimizes the leakage current flow between drain contact 204₃ and source contact 202₄. In some examples, drain contacts 204ᵢ may be hybrid drain contacts. Leakage cut-off structure 218 can have similar function as leakage blocking structure 270 of FIG. 4A and/or high threshold voltage structures 218 but with different geometries, such as having uneven width (e.g., a narrower width in the middle as shown). In FIG. 5, leakage cut-off structure 218 can be spaced from boundary 235 by a distance of, for example, 0.1 to 5 um. In some examples, leakage cut-off structure 218 can also overlap boundary 235.

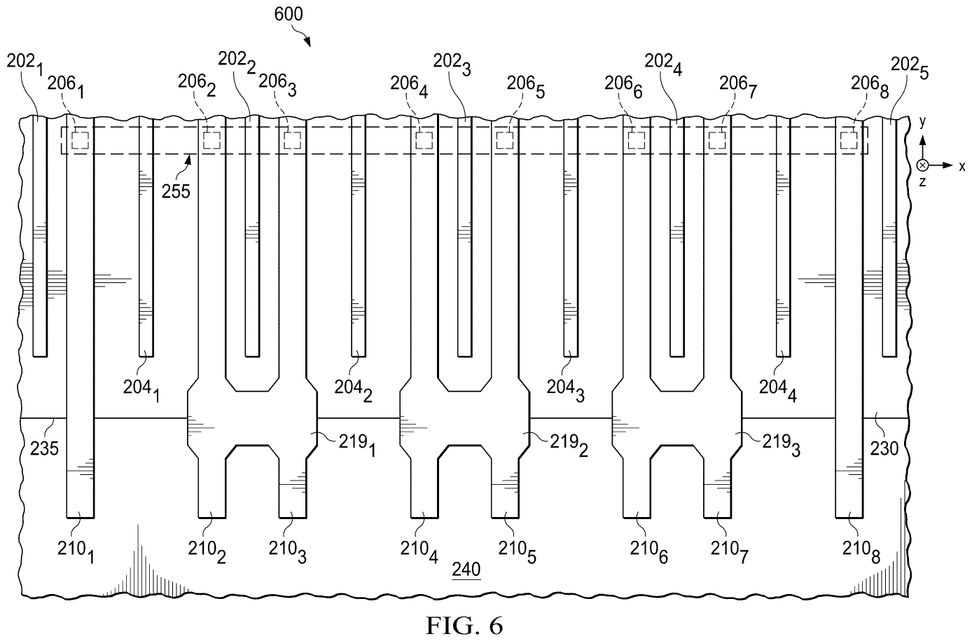

FIG. 6 is a plan view of a semiconductor device 600 according to some examples. Semiconductor device 600, which in this example is a FET, includes, in part, a multitude of parallel gate fingers 210ᵢ, 8 of which, namely 210₁, 210₂ . . . 210₈ are shown in FIG. 6. Positioned along opposing sides of each gate finger 210ᵢ (i is an index ranging from 1 to 8 in this example) are a source contact, and a drain contact. Although not shown, it is understood that gate fingers 210ᵢ are connected to one another via a first metal interconnect; source contacts are connected to one another via a second metal interconnect; and drain contacts are connected to one another via a third metal interconnect. Boundary line 235 is defined by a patterned mask separating active region 230 of FET 600 from isolation region 240. Isolation region 240 is formed by implanting ions to inhibit the formation of a 2 DEG region due to, for example, the damage to imparted to semiconductor crystals during the implantation.

To mitigate current leakage as a result of the lower subthreshold voltage near the boundary between the active region 230 and isolation region 240, the edges of each gate finger running parallel to the y-direction are extended along both positive and negative x directions such that the gate fingers positioned on opposing sides of each source contact merge to form a leakage cut-off structure that overlaps both active region 230 and isolation region 240. For example, leakage cut-off structure 219₁, shown as connecting extended gate fingers 210₂ and 210₃, minimizes the leakage current flow between drain contacts 204₁/204₂ and source contact 202₂. In a similar manner, leakage cut-off structure 219₂, shown as connecting gate fingers 210₄ and 210₅, minimizes the leakage current between drain contact 204₂/204₂ and source contact 202₃; and leakage cut-off structure 219₃, shown as connecting gate fingers 210₆ and 210₇, minimizes the leakage current between drain contact 204₃/204₄ and source contact 202₄. In some examples, drain contacts 204ᵢ may be hybrid drain contacts. In some examples, each leakage cut-off structure 219 can be formed from merging high threshold voltage structures 218 of FIG. 4B. Leakage cut-off structures 219 can overlap boundary 235 as shown in FIG. 6, or can be spaced from boundary 235 by a distance of, for example, 0.1 to 5 um.

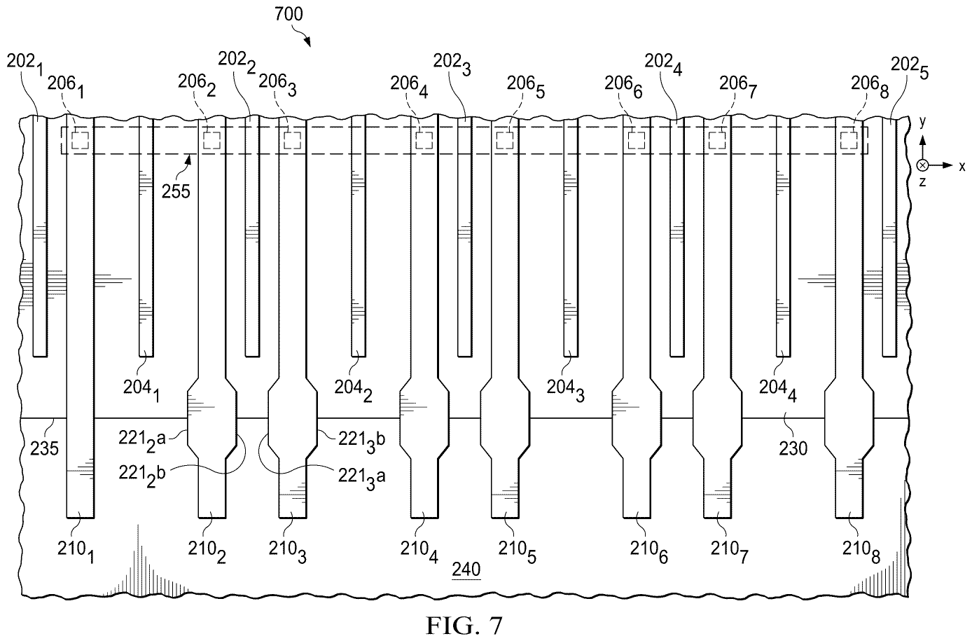

FIG. 7 is a plan view of a semiconductor device 700 according to some examples. Semiconductor device 700, which in this example is a FET, is similar to FET 600 except that in FET 700, the extended edges of gate fingers along positive and negative x directions do not merge. For example, extended edge 221₂b of gate finger 210₂ does not merge with extended edge 221₃a of gate finger 210₃. However, the larger gate area caused by the extended edges of each gate finger mitigates the leakage current between associated drain contacts and source contacts. For example, the larger gate areas and the attendant longer channels stemming from extended edges 221₂a and 221₂b of gate finger 210₂ and extended edges 221₃a and 221₃b of gate finger 210₃ minimize the leakage current between drain contact 204₁/204₂ and source contact 202₂. The extended edges of each gate finger partially overlap the isolation region 240, as shown. In some examples, drain contacts 204ᵢ may be hybrid drain contacts. In some examples, the extended edges 221 can form high threshold voltage structures 218 of FIG. 4B. The extended edges 221 can overlap boundary 235 as shown in FIG. 7, or can be spaced from boundary 235 by a distance of, for example, 0.1 to 5 um.

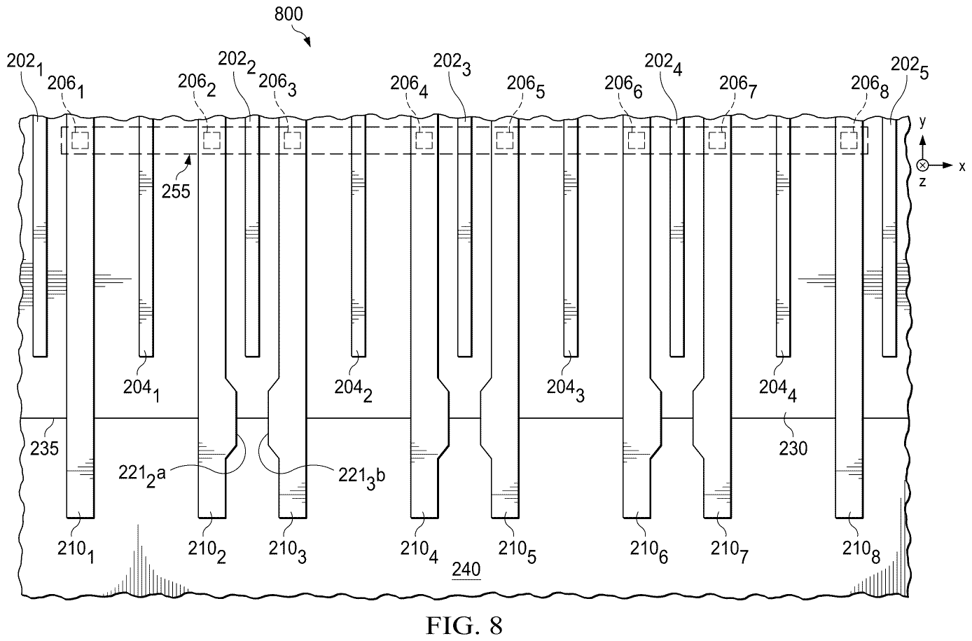

FIG. 8 is a plan view of a semiconductor device 800 according to some examples. Semiconductor device 800, which in this example is a FET, is similar to FET 700 except that in FET 800, only the edge of each gate finger facing a source contact is extended along the x direction. For example, the edge of gate finger 210₂ facing source contact 220₂ is extended along the positive x direction to form extended edge 221₂a. Similarly, the edge of gate finger 210₃ facing source contact 220₂ is extended along the negative x direction to form extended edge 221₃b. The larger gate areas resulting from the extended edges of the gate fingers mitigate the leakage current between drain and source contacts. For example, the larger gate area stemming from extended edge 221₂a of gate finger 210₂ and extended edge 221₃b of gate finger 210₃ minimizes the leakage current between drain contacts 204₁/204₂ and source contact 202₂. In some examples, drain contacts 204ᵢ may be hybrid drain contacts. The extended edges 221 can overlap boundary 235 as shown in FIG. 8, or can be spaced from boundary 235 by a distance of, for example, 0.1 to 5 um.

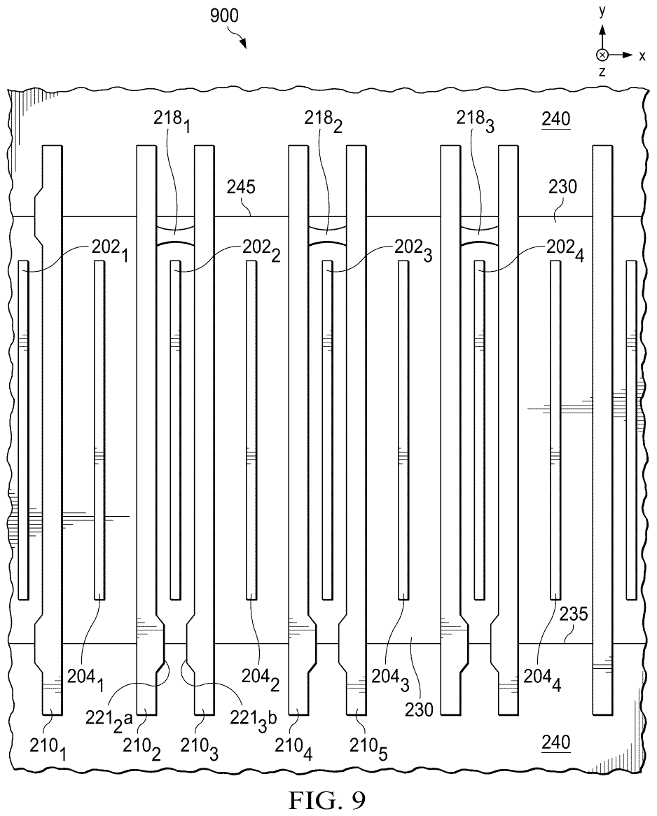

FIG. 9 is a plan view of a semiconductor device 900 according to some examples. Semiconductor device 900, which in this example is a FET, is similar to FET 800 except that in FET 900 adjacent gate fingers positioned on opposing sides of each source contact are connected to one another via a leakage cut-off structure in the active region near the other boundary 245 separating active region 230 from isolation region 240. For example, leakage cut-off structure 218₁, shown as connecting gate fingers 210₂ and 210₃ in active region 230 near boundary 245, minimizes the leakage current between drain contacts 204₁/204₂ and source contact 202₂. In a similar manner, leakage cut-off structure 218₂, shown as connecting gate fingers 210₄ and 210₅, minimizes the leakage current between drain contacts 204₂/204₃ and source contact 202₃. In some examples, drain contacts 204ᵢ may be hybrid drain contacts. Edges 221 can overlap boundary 235 (as shown) or can be spaced from boundary 235 by, for example, 0.1 to 5 um. Leakage cut-off structures 218 can be spaced from boundary 245 by, for example, 0.1 to 5 um, or can overlap boundary 245.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A semiconductor device comprising:
a semiconductor layer including an isolation region and an active region;
first, second, and third contacts being at least partially on the active region; and
first and second gates extending from the active region into the isolation region, the first gate being laterally between the first and second contacts, and the second gate being laterally between the second and third contacts, the first and second gates including, respectively, first and second leakage blocking extensions that are proximate a boundary between the isolation region and the active region.

2. The semiconductor device of claim 1, wherein the first and second leakage blocking extensions overlap the boundary.

3. The semiconductor device of claim 1, wherein the first and second leakage block extensions join and form a continuous extension.

4. The semiconductor device of claim 1, wherein the first and second leakage block extensions are spaced apart from each other.

5. The semiconductor device of claim 1, wherein the first and second leakage blocking extensions provide a higher threshold voltage for enabling a channel than portions of the active region that do not include the leakage blocking extensions.

6. The semiconductor device of claim 5, wherein:
the first gate is laterally between the first and second contacts along a first direction,
the second gate is laterally between the second and third contacts along the first direction,
each of the first and second gates has a portion having a first length along the first direction,
each of the first and second leakage blocking extensions has a second length along the first direction; and
the second length is larger than the first length.

7. The semiconductor device of claim 5, wherein:
the first gate is laterally between the first and second contacts along a first direction,
the second gate is laterally between the second and third contacts along the first direction,
a first metal covering the first gate has a narrower width in the first leakage blocking extension than in remaining portion of the first gate; and
a second metal covering the first second has a narrower width in the second leakage blocking extension than in remaining portion of the first gate.

8. The semiconductor device of claim 1, wherein the semiconductor layer includes a GaN buffer layer, the semiconductor device further comprising an AlGaN barrier layer on the GaN buffer layer, and the first, second, and third contacts are at least partially on the AlGaN barrier layer.

9. The semiconductor device of claim 8, wherein each of the first and second gates includes a respective p-type Gallium Nitride (pGaN) layer.

10. The semiconductor device of claim 8, wherein the AlGaN barrier layer has a first thickness over the active region and a second thickness over the isolation region, the second thickness being larger than the first thickness.

11. A semiconductor device comprising:
a semiconductor layer including an isolation region and an active region;
first, second, and third contacts being at least partially on the active region; and
first and second gates extending from the active region into the isolation region, the first gate being laterally between the first and second contacts, and the second gate being laterally between the second and third contacts; the first and second gates each having a first region and a second region, the second regions of the first and second gates proximate a boundary between the isolation region and the active region, the second regions having a higher threshold voltage for enabling a channel than the first regions.

12. The semiconductor device of claim 11 wherein:
each of the first and second gates has a portion having a first length along the first direction,
each of the first and second gates has a second length along the first direction; and
the second length is larger than the first length.

13. The semiconductor device of claim 11 wherein:
a first metal covering the first gate has a narrower width in the second region of the first gate than a first region of the first gate; and
a second metal covering the second gate has a narrower width in the second region of the second gate than a first region of the second gate.

14. The semiconductor device of claim 11, wherein the semiconductor layer includes a GaN buffer layer, the semiconductor device further comprising an AlGaN barrier layer on the GaN buffer layer, and the first, second, and third contacts are at least partially on the AlGaN barrier layer.

15. The semiconductor device of claim 14, wherein each of the first and second gates includes a respective p-type Gallium Nitride (pGaN) layer.

16. The semiconductor device of claim 14, wherein the AlGaN barrier layer has a first thickness over the active region and a second thickness over the isolation region, the second thickness being larger than the first thickness.

17. The semiconductor device of claim 15, wherein the GaN buffer layer has a first thickness over the active region and a second thickness over the isolation region, the second thickness being smaller than the first thickness.

18. A semiconductor device comprising:
a first semiconductor layer including an isolation region and an active region;
first, second, and third contacts being at least partially on the active region; and
first and second gate structures, the first and second gate structures each including a second semiconductor layer extending from the active region into the isolation region, the second semiconductor layer of the first gate structure being laterally between the first and second contacts, and the second semiconductor layer of the second gate structure being laterally between the second and third contacts, the first and second gate structures each having a first region and a second region, the second regions of the first and second gate structures proximate a boundary between the isolation region and the active region, the second regions having a different structure from the first regions.

19. The semiconductor device of claim 18 wherein the second region of the first gate structure is connected to the second region of the second gate structure in the active region.

20. The semiconductor device of claim 18 wherein the second region of the first gate structure is connected to the second region of the second gate structure in the active and isolation regions.

21. The semiconductor device of claim 18 wherein a width of the second regions of the first and second gate structures is greater along first and second directions than a width of the first regions of the first and second gate structures along the first and second directions.

22. The semiconductor device of claim 18 wherein a width of the second region of the first gate structure is greater along a first direction than a width of the first region of the first gate structure along the first direction, and wherein a width of the second region of the second gate structure is greater along a direction, opposite the first direction, than a width of the first region of the second gate structure along the first direction.

23. The semiconductor device of claim 18 wherein a first portion of the second region of the first gate structure is connected to a first portion of the second region of the second gate structure in the active region, and wherein a width of a second portion of the second region of the first gate structure is greater along a first direction than a width of the first portion of the first region of the first gate structure along the first direction, and wherein a width of a second portion of the second region of the second gate structure is greater along a direction, opposite the first direction, than a width of the second portion of the first region of the second gate structure along the first direction, wherein said first portions of the second regions of the first and second gate structures are physically distinct from said second portions of the second regions of the first and second gate structures.

24. The semiconductor device of claim 18, wherein the semiconductor layer includes a GaN buffer layer, the semiconductor device further comprising an AlGaN barrier layer on the GaN buffer layer, and the first, second, and third contacts are at least partially on the AlGaN barrier layer.

25. The semiconductor device of claim 24, wherein each of the first and second gate structures includes a respective p-type Gallium Nitride (pGaN) layer.
